(19) United States
(12) Patent Application Publication
(10) Pub. No.: US 2025/0280511 A1
(43) Pub. Date: Sep. 4, 2025

(54) NANO/MICRO-CHANNEL EVAPORATOR FOR THERMAL MANAGEMENT

(71) Applicant: SYRACUSE UNIVERSITY, Syracuse, NY (US)

(72) Inventors: Shalabh Maroo, Jamesville, NY (US); Durgesh Ranjan, Gainesville, FL (US)

(73) Assignee: SYRACUSE UNIVERSITY, Syracuse, NY (US)

(21) Appl. No.: 19/052,120

(22) Filed: Feb. 12, 2025

Related U.S. Application Data
(60) Provisional application No. 63/552,577, filed on Feb. 12, 2024.

(51) Int. Cl. H05K 7/20

(52) U.S. Cl. CPC H05K 7/20309

(57) ABSTRACT

An evaporator for purposes of thermal management of various electronic devices includes one or more supporting planar structures. A plurality of nano/micro-channels are formed in a surface of each of the one or more supporting planar structures, the plurality of nano/micro-channels being in parallel and spaced relation to one another. A pair of reservoirs may be disposed at opposing ends of the evaporator in which at least one of the reservoirs contains a quantity of a heat dissipative fluid. In at least one version, a plurality of single plane evaporators can be formed in a vertically stacked configuration, which is supported by at least one manifold(s) configured to permit heat dissipative fluid to enter and exit each evaporator.

### CROSS REFERENCES TO RELATED APPLICATIONS

This application claims priority to USSN 63/552,577, entitled: NANO/MICRO-CHANNEL EVAPORATOR FOR THERMAL MANAGEMENT, which was filed Feb. 12, 2024, under relevant portions of 35 USC § 119 and 35 USC § 120, the entire contents of which are herein incorporated by reference.

### STATEMENT REGARDING FEDERALLY SPONSORED RESEARCH OR DEVELOPMENT

Not Applicable

### REFERENCE TO SEQUENCE LISTING OR COMPUTER PROGRAM LISTING APPENDIX

Not applicable.

### TECHNICAL FIELD

This application is generally directed to the field of heat dissipation and more specifically to a compact evaporator that is configured with one or more plates or similar supporting structures. Each of the plates/supporting structures, which can be defined by a single layer of stacked arrangement of several layers, include an array of nano/micro-channels containing a working fluid for purposes of thermal management.

### BACKGROUND

Phase-change heat transfer, such as transpiration and surface evaporation, is generally ubiquitous in nature, as well as in numerous industrial applications, such as power generation and desalination. Thermal management solutions for integrated circuits (ICs) used in electronic devices frequently use evaporation, a multiphase heat transfer mechanism, to maintain the temperature of such devices in their operational range. Ongoing miniaturization of ICs would require the evolution of effective thermal management in order to dissipate localized heat generation and attain a suitable (1 KW/cm²) heat flux removal in the near future. Additionally, space constraints in such devices require small form factor cooling solutions and have led to several approaches, including microchannel heat sinks, embedded cooling, nano/micro-structured heat pipes, and graphene heat spreaders, among others. Regardless of the device type or design, a thin film evaporation-based cooling approach using heat pipes is considered one of the more prominent known techniques for heat dissipation, prompting several studies to address on-chip hot spot thermal management. Such devices rely on passive capillary-driven flow of working fluids, such as water, refrigerants, and alcohol, as enabled by porous wicks.

Numerous wick materials and fabrication techniques, namely metallic pillars, sintering, and 3D-printed metal have been investigated to improve the thermal performance of evaporation in heat pipes. Recent studies reporting interfacial evaporative in the confined space on the order of 0.5−11 kWm⁻² K⁻¹ provide insight into the potential of thin-film evaporation-based devices for effective thermal management. However, the accuracy of evaporative heat flux calculations with any fluid-wick structure combination directly depends on the reliability of contact angle (CA) measurements taken at the meniscus, because the contact angle governs the pressure gradient that is required for capillary flow. The contact angle acquired from the meniscus image(s), or Young-Laplace equation in the confined space may not be accurate because this calculation is susceptible to error in the detection of the three-phase contact line and the limitations associated with the camera/microscope field of view. Consequently, other studies have used the augmented Young-Laplace model, interferometry and different contact angles for top and side walls of high-aspect-wick in order to capture accurate apparent contact angles of fluid. In addition to the reliability of CA measurement, high interfacial heat flux is typically reported for wick distances of just a few microns. It should be noted that the foregoing designs are prone to “dry out,” and also may be limited for purposes of practical applications. The evaporative performance relies heavily upon maintaining the thin liquid film at the interface governed by capillary pressure and viscous pressure drop in the wick/porous structure.

Although a decrease in the geometrical parameters of the wick design enhances capillarity, increased viscous resistance restricts fluid flow. For a characteristic length of ‘L’ of a typical wick structure with wick distance ‘D’ between the liquid source and evaporation zone, capillarity scales as L⁻¹. By way of contrast, hydrodynamic resistance scales as DL⁻². Therefore, momentum transport poses a significant challenge in the evaporator design of a heat pipe or similar structure. Furthermore, the choice of a suitable working fluid is dictated by the physical properties of the working fluid, the requirement for heat dissipation, suitability for the application site, and potential risks. Although water offers high surface tension and high latent heat relative to its viscosity, the choice of a low viscosity working fluid is more desirable for electronics applications than water and with even better performance. Among these fluids, 3M Fluorinert electronic fluid FC72, with its dielectric properties, has been found to be a suitable working fluid in oscillating heat pipes and has demonstrated superior heat transfer performance over water using gas-assisted thin film evaporation. At lower film thicknesses, the volatility benefit of FC72 over water plays a critical role in attaining a relatively higher heat flux, even with its low thermal conductivity.

### BRIEF DESCRIPTION

Therefore and according to at least one aspect, there is provided an evaporator for purposes of thermal management of one or more devices, the evaporator comprising one or more supporting structures (i.e., plates or substrates); as well as an array of nano/micro-channels formed in a top and/or bottom surface of each of the one or more supporting structures. The array of nano/micro-channels are in parallel relation to one another; wherein the evaporator further comprises a pair of reservoirs, each reservoir being disposed at an opposing end of the evaporator in which at least one of the reservoirs contains a quantity of a working fluid.

According to at least one version, the supporting structure of the evaporator is a silicon wafer of suitable size, in which the array of nanochannels and micro-reservoirs being fabricated into a top and/or bottom surface of the wafer. A glass or other suitable structure/substrate can be used to cover the evaporator, wherein the covering structure includes at least one opening aligned with one or both of the micro-reservoirs to enable addition of the working fluid.

According to at least one version, a three-dimensional configuration can be created in which two or more of the nano/micro-channel evaporators can be arranged in a vertically stacked arrangement that can be supported at respective ends to a manifold to achieve enhanced thermal management via high heat dissipation, which will also be dynamic in nature.

An advantage realized is that of improved thermal management suitable for a number of electronic devices and applications given the low profiled structural design of the evaporator, even in a vertically stacked version. That is, the design of the herein-described evaporator enables high heat flux removal with an extremely low profile. In addition, the evaporator provides dynamic or self-tuning capability of heat removal.

These and other features and advantages will be readily apparent from the following Detailed Description, which should be read in conjunction with the accompanying drawings.

### BRIEF DESCRIPTION OF THE DRAWINGS

FIG. 1(a) is a top perspective view of an exemplary nano/microchannel evaporator, which is made in accordance with embodiments of the present disclosure;

FIG. 1(b) is an atomic force microscopic (AFM) image of a nanochannel of the evaporator of FIG. 1(a);

FIG. 1(c) illustrates a variation of the depth of a nanochannel of the evaporator of FIGS. 1(a) and 1(b), as taken across its width.

FIG. 1 (d) is a perspective view of the evaporator of FIGS. 1(a)-1(c), as used in an experimental setup;

FIG. 1(e) is a micrograph of the nano/microchannel evaporator of FIG. 1(a) made in accordance with an alternative embodiment, in which silicon is disposed between the nanochannels;

FIG. 2(a) is a schematic view of an experimental setup including arrangements of nano/microchannel evaporators made in accordance with one or more embodiments of the present disclosure, the experimental setup including a resistive heater at the bottom, over-the-top tube reservoirs, and a plastic support arranged between the nanochannel evaporator and a base plate;

FIG. 2(b) is a illustrates an experimental setup for enabling a microscope view of a fluid meniscus to be observed in one or more nanochannels of the evaporator of FIG. 2(a);

FIG. 2(c) illustrates a setup of an experiment set up for capturing a temperature distribution across the nano/microchannel evaporator of FIGS. 2(a) and 2(b) using an IR (infrared) camera;

FIG. 2(d) illustrates the experimental setup for the wicking of working fluid in the nanochannels of the nano/microchannel evaporator of FIGS. 2(a)-2(c), with one end micro-reservoir being filled while keeping the opposing end micro-reservoir empty;

FIG. 3(a) is a graphical representation of the wicking distance of wicking fluid of the nano/microchannel evaporator as a function of the square root of time in which the inset depicts the actual liquid front and corresponding procedure used to obtain the wick length;

FIG. 3(b) is a graphical representation depicting variations in the velocity of the actual liquid front over time, with the inset depicting the menisci in the nanochannels of the evaporator;

FIG. 3(c) depicts a calibration of weight loss from decrease in working fluid level on the reservoir scale with weight loss being recorded by the weighing scale of the experimental setup in the inset;

FIG. 3(d) is a graphical representation of emissivity calibration of the evaporator for a predetermined emissivity (=0.92) as performed by the experimental setup, shown in the inset;

FIG. 4(a) (i), (ii), and (iii) represents an observation in heated conditions of the nano/microchannel evaporator with the nanochannels dry out without nucleation at a temperature (88° C.) that is significantly higher than the boiling point of a specific working fluid (FC72);

FIG. 4(b), (i), (ii) and (iii) represents a further observation in heated conditions of stable menisci at different locations of the nano/microchannel evaporator from reservoirs depending on the heat flux input;

FIG. 4(c) represents a further observation in heated conditions illustrating a variation of temperature near the left reservoir (L), right reservoir (R), and above the resistive heater (C) after stable menisci have been achieved;

FIG. 5(a) represents nano/microchannel evaporator performance at different heat flux inputs and more specifically a variation of evaporative mass flux (m, left y-axis, as shown) and stable wicking distance measured from the reservoir (right y-axis);

FIG. 5(b) represents variation of the interfacial evaporative heat flux (left y-axis), and product of stable wicking distance with the interfacial evaporative heat flux (right y-axis, as shown);

FIG. 5(c) illustrates evaporative cooling efficiency of the nano/microchannel evaporator at different heat flux input levels;

FIG. 6(a) illustrates heat loss estimations based on COMSOL simulation analysis and more specifically a three-dimensional model of evaporator arrangement and temperature variation across multiple sources of heat loss for a predetermined power level;

FIG. 6(b) further illustrates heat loss estimations based on COMSOL simulation analysis and more specifically a comparison of maximum recorded temperature and thermocouple (TC) over heater;

FIG. 6(c) further illustrates heat loss estimations based on COMSOL simulation analysis and more specifically a distribution of natural convection heat loss from a base plate (Qₐₗₐₘ), reservoir tubes (Qₚₜ), a base under the evaporator (Q_{pb}), evaporator bottom (Q_{wb}), and evaporator top (Q_{wt}) of the experimental setup;

FIG. 7 illustrates sequential views of fabrication procedure of a nano/microchannel evaporator in accordance with aspects of the present disclosure;

FIG. 8(a) illustrates a resistive heater used in the nano/microchannel evaporator in accordance with aspects of the present disclosure;

FIG. 8(b) illustrates an assembly of the heater of FIG. 8(a) and the nano/microchannel evaporator in accordance with aspects of the present disclosure

FIG. 8(c) depicts various wires soldered on copper electrodes and thermocouple attached to the heater of FIGS. 8(a) and 8(b);

FIG. 9(a) relates a heat loss COMSOL estimation including a three-dimensional model of evaporator arrangements for the estimation;

FIGS. 9(b)-9(d) depict temperature variation across multiple sources of heat loss for specified power levels (0.92 W, 1.63 W, and 2.20 W);

FIG. 10 illustrates various exploded views and a top plan view of a nano/microchannel evaporator which is made accordance with an alternative exemplary embodiment of the present disclosure;

FIG. 11 illustrates various exploded views and a side elevational view, partially assembled, of the nano/microchannel evaporator of FIG. 10;

FIG. 12 illustrates various perspective, top and side views of a manifold for use in the vertically stacked nano/microchannel evaporator of FIGS. 10 and 11; and

FIG. 13 illustrates various perspective, side elevational, side and top views of the vertically stacked nano/microchannel evaporator in a fully assembled condition, including the manifold of FIG. 12.

### DETAILED DESCRIPTION

The following description relates to various exemplary embodiments and experimental setups of a nano/microchannel evaporator for purposes of thermal management of electronic devices, as well as other suitable applications. Various terms are used throughout this discussion to provide a suitable frame of reference with regard to the accompanying drawings. These terms, however, and unless so specifically defined, are not intended to limit the overall scope of the following disclosure unless so specifically indicated. It will further be readily apparent that there are a number of variations and modifications that can be made within the intended scope of this disclosure, including those of the appended claims. In addition, the drawings are provided to illustrate salient aspects of the evaporator and should not be relied upon for scaling purposes.

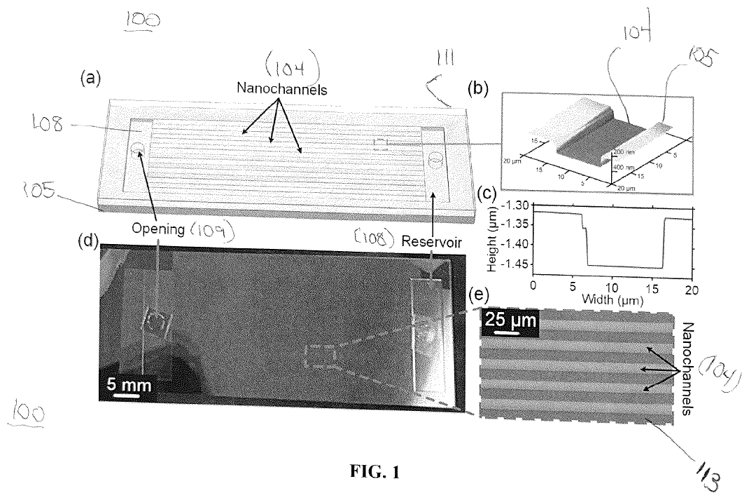

In brief and as described in greater detail herein with reference to FIG. 1(a), a nano/microchannel evaporator 100 according to a first exemplary embodiment is made up of an array of nano/microchannels 104. The array of nano/microchannels 104 are formed in a singular silicon supporting structure 105 (a wafer) along with micro-reservoirs 108 that are formed at opposing ends of the supporting structure and in communication with the formed array of nano/microchannels 104. According to this specific embodiment, a substrate 111 is sized and configured to cover the top of the silicon supporting structure 105, the latter covering structure including openings 109 over one or both of the end micro-reservoirs 108. In at least one version, the covering substrate 111 can be made from glass, although other materials can be utilized.

A suitable heat dissipating (working) fluid (in this instance 3MTM Fluorinert™ Electronic Fluid—FC72) is entered into the device 100 through one or more of the openings 109 that are formed in the covering structure 111. FC72 is a well known clear, non-conductive, thermally and chemically stable fluid that is ideal for many single or multi-phase heat transfer applications, which is also non-flammable and possesses a very narrow boiling range. Creating an evaporator that is compatible with this working fluid is therefore highly advantageous. It will be understood, however that other suitable working fluids, such as ethylene glycol or water, can also be utilized. In accordance with this embodiment, the formed openings are provided directly over the reservoirs 108 and are disposed at opposing ends of the glass structure 111. Details relating to a fabrication methodology for the herein described device 100, now follow.

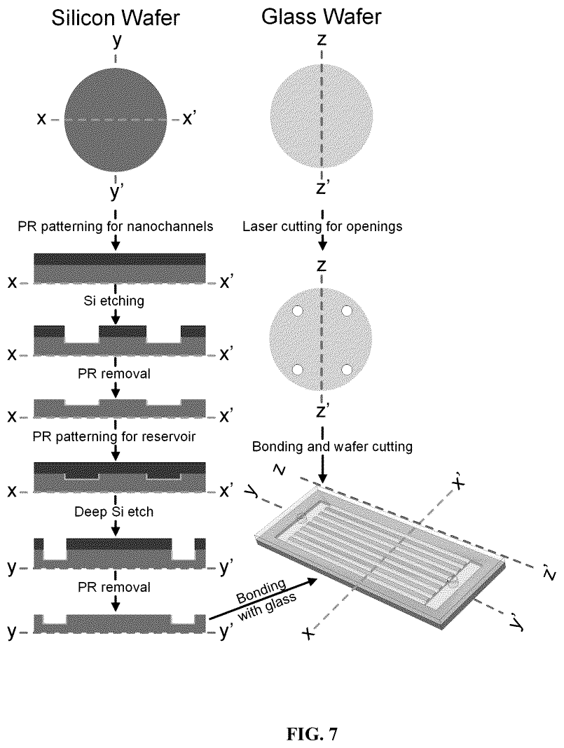

A working example is herein described. The array of nano/microchannels 104 according to this specific methodology and according to this working example are fabricated in a four-inch silicon anodic wafer that is bonded with a corresponding four-inch glass wafer, as shown for purposes of this discussion in FIG. 7. More specifically, the fabrication of the array of nano/microchannels 104 and end reservoirs 108 starts with a suitably sized silicon wafer 700. In this specific example, the wafer 700 is 500 μm in thickness and 4 inches in diameter. According to this specifically described embodiment, the array of channels 104 formed in the silicon wafer are nanochannels and the end reservoirs 108 are micro-reservoirs. Specific equipment is herein described for purposes of fabrication according to this working example, although it will be readily apparent that each are merely examples.

A first stage of fabrication starts with wafer cleaning in a hot bath for 10 minutes in each of three (3) tanks (heated solvent for photoresist stripping) followed by drying in a spin rinse dryer (Micron, VERT9A0110). A 60 nm DUV 42P ARC layer and 600 nm UV210 photoresist coating are then deposited onto the wafer using Gamma Automatic coat-develop tool (Suss MicroTec Gamma Cluster Tool). After the exposure using an ASML PAS 5500/300C DUV wafer stepper, the silicon wafer was hard baked (at 135° C. for 90 seconds) and developed using a Hamatech wafer processor (process used: 726 MIF 60 seconds). Starting with 10 minute oxygen cleaning, 120 seconds ARC seasoning, 105 seconds ARC etching, 5 minutes oxygen cleaning, 2 minutes CF₄ seasoning, dry silicon etching for the nano/microchannels was performed using Oxford PlasmaLab 80+ RIE System, followed by atomic force microscopy (Veeco Icon atomic force microscope) to acquire the nanochannel dimensions.

In a second stage, the end reservoirs 108, which according to this exemplary embodiment are micro-reservoirs, were fabricated 48 mm apart at respective ends such that the array of formed nanochannels 104 function as bridges interconnecting the micro-reservoirs 108. The nanochannel etched wafer was plasma cleaned (Glen 1000P plasma cleaning system) at 400 W for 10 minutes and manually spin coated with SPR 220-3 photoresist to obtain a ˜3 μm coating on the wafer. The wafer was then soft baked at 115° C. for 90 seconds. A contact aligner (ABM high resolution mask aligner) was used to expose the photoresist at the locations of the micro reservoirs 108 using a custom made mask. According to this embodiment, it should be noted that each wafer yielded two (2) nanochannel evaporators. Therefore, two micro-reservoirs 108 were exposed on either side of the formed array of nanochannels 104. After hard baking at 115° C. for 90 seconds and wafer development using a Hamatech wafer processor, 20 μm deep reservoirs were etched, in this working example, using a Plasma-Therm deep silicon etcher. The wafer was then kept overnight in a hot bath to remove the photoresist followed by polymer layer stripping in a Anatech strip tool at 900 W for 15 minutes.

In a third stage of fabrication, the silicon wafer was bonded with the glass wafer, the latter acting as the cover substrate 111. The glass wafer was cleaned, and 3 mm openings were laser cut (using a VersaLaser VLS3.50) such that the openings preferably coincided directly with the center of the end microreservoirs 108. Anodic bonding using a Suss SB8e VAC substrate bonder (recipe included: temp=300° C., voltage=800V, time=30 min) was then performed. Finally, the evaporator was cut into a predetermined or required size from bonded wafers, for example, using a DISCO dicing saw.

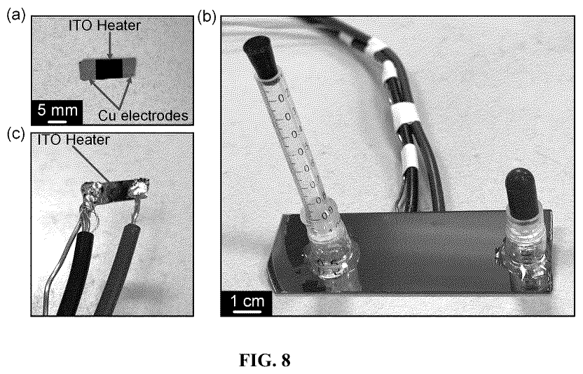

Depending on the requirements, either a single opening or both of the openings provided in the glass covering structure can be used to supply the working fluid to the nano/microchannel evaporator. For purposes of experimental study and with reference to FIGS. 8(a)-8(C), a heater, such as a resistive heater, was attached in the center and bottom of the evaporator along with a thermocouple. Subsequently, a film of Indium-Tin Oxide (ITO) was deposited on a separate 500 um silicon wafer using a Kurt J. Lesker sputtering tool (Temp: 200° C., O2: 2%, thickness ˜60 nm). As further shown, copper electrodes on the ITO film were vapor-deposited using a CVC SC4500 Combination Thermal/E-gun Evaporation System. Pieces of the heater were cut using a DISCO dicing saw.

Atomic force microscopy (performed during fabrication) on an exemplary nanochannel 104 cross section is shown in FIGS. 1(b) and 1(c), respectively. In this specific version, the average depth of a nanochannel 104 of the herein described evaporator 100 is approximately 122 nm and the average width of a nanochannel is approximately 10 microns, wherein an array of more than 1000 nanochannels (e.g., 1100) are fabricated, with the overall thickness of the herein described evaporator 100 being approximately 1 mm in thickness. Each of the end micro-reservoirs 108 according to this embodiment were made having dimensions of approximately 22 mm×6 mm with the length of the nanochannels 105 interconnecting the micro-reservoirs 108 being approximately 48 mm. It should be readily understood that the foregoing parameters are exemplary for this embodiment, and therefore can be suitably varied depending on the application or use thereof.

A top view of the herein fabricated evaporator is shown in FIG. 1(d). Tape sections covering the openings were added, as shown in FIG. 8(a) for the following described experiments in order to keep the end micro-reservoirs 108 clean and until a set of tube reservoirs were later attached in advance of various experiments, as discussed below. FIG. 1(e) presents a micrograph of a portion of the evaporator 100, showing the alternating nanochannels 104 and silicon ridges 113, each having a width of about 10 microns according to this specific embodiment.

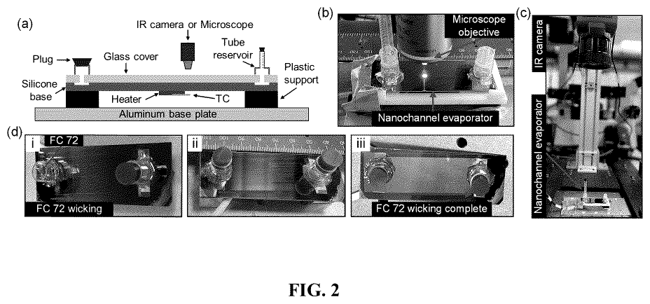

FIG. 2(a) is a schematic view of an experimental setup having the set of tube reservoirs with sealing plugs, a heater, plastic support, and an aluminum base plate, each attached to the herein described evaporator 100. The meniscus movement of the contained working fluid was tracked and visualized under a microscope, as shown in FIG. 2(b), and the location of the meniscus from the micro-reservoir (i.e., wicking distance) 108 was determined using a reference scale that was placed beside the micro-reservoir 108. The tube reservoir shown on the left in FIG. 2(b) was longer than the corresponding right side reservoir because the former reservoir was primarily used to hold the working fluid during the evaporator experiments, and the scale markings (least count: 0.01 mL) on its curved surface estimated the amount of working fluid that evaporated during the experiments. At each input heat flux, the evaporation was first observed under a microscope, and then temperature was also monitored, in this instance using an infrared (IR) camera, as shown in FIG. 2(c). In addition and for purposes of this particular experimental study, the temperature distribution on the evaporator 100 was recorded for 120 seconds after achieving steady state (approximately 20 minutes after heat flux supply).

FIG. 2(d) depicts successive images of working fluid wicking (at no supplied heat flux) in the nanochannels 104 of the evaporator 100, as shown by a relative shift in color and contrast during the process. The working fluid gradually floods the nanochannels 104 over its length and entirely to the remaining micro-reservoir 108.

As previously discussed, the fabrication of the nanochannel evaporator according to this specific embodiment began with a 4-inch 500 micron thick silicon wafer involving dedicated and conventionally known photolithography procedures, which do not form a part of the present invention. The array of adjacent parallel nanochannels 104 were fabricated orthogonally relative to the end micro-reservoirs 108, the latter having dimensions of about 22 mm×6 mm×20 microns. A borofloat glass wafer used as the glass covering structure 111 underwent anodic bonding with the silicon wafer such that the opening(s) 109 in the glass wafer were disposed over the micro-reservoirs 108. After dicing, each bonded wafer yielded two (2) nanochannel evaporator samples. The heater attached to the bottom of the evaporator was separately fabricated. As shown in FIGS. 8(a)-8(c), heater fabrication started with a silicon wafer on which a 90 nm thick indium tin oxide (ITO) film was deposited by physical vapor deposition (PVD). A 500 nm thick copper layer was then deposited as electrodes. The ITO film between the copper electrodes acted as a joule heater when a direct current passes through it.

As previously noted, FC 72 was used as an exemplary heat dissipating or working fluid in the evaporator given its overall physical properties and relatively low boiling point. Plastic tubes acting as reservoirs (the afore mentioned “tube reservoirs”) attached above the micro-reservoir opening 109 were commercially available syringes for purposes of this embodiment that were trimmed to a required or predetermined size. Micrographs of the nanochannel sample were captured using an upright microscope (in this instance Nikon, Eclipse-LV150NL). The surface topography of the sample was analyzed by atomic force microscopy (AFM) using a Vecco Icon AFM tool. Weight measurements were recorded using a Pioneer analytical weighing scale (model; PX224/E, least count: 0.1 mg) connected to a computer. A high speed camera (such as Phantom, V611) captured the working fluid wicking in the nanochannels 104 that was later used to obtain values of liquid front velocity by performing image analysis through a custom MATLAB script. The temperature was recorded using a combination of K-type thermocouple connected to the data acquisition system (National Instruments, NI 9211). An infrared (IR) camera (A6753SC, FLIR Systems) was used to record the evaporator temperature distribution at different input heat flux.

In lieu of an electronic device and for purposes of the experimental study, heat flux was provided by the resistive heater attached, such as described above, to the bottom of the evaporator 100, which was powered by a DC power supply. The performance of the evaporator 100 was then analyzed using a microscope to visualize the menisci behavior of the working fluid. Menisci steady state was achieved when the stable liquid front was confirmed under the microscope, which generally occurred in this particular experimental study about 20 minutes of any change in the supplied heat flux. Furthermore and at each heat flux, according to this example, the experiment was repeated under an infrared (IR) camera in order to record the temperature distribution.

Numerical analyses to compute heat losses during these performed experiments and working example was performed in COMSOL Microphysics. The built-in surface integral of heat flux function was used to calculate the natural heat convection losses (from the aluminum base plate (Q), reservoir tubes (Q), plastic base under the evaporator (Q), evaporator bottom (Q), and evaporator top (Q)) associated with the model at steady state.

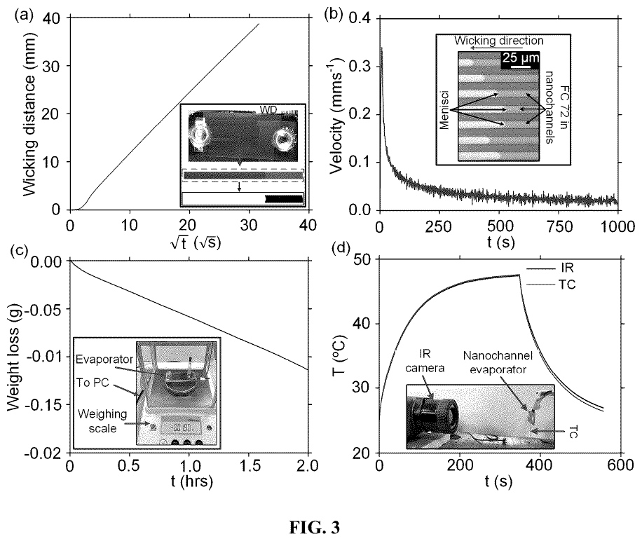

The wicking of fluids in the various nano/microchannels 104 of the evaporator 100 is attributed to capillary pressure and the motion of liquid within the evaporator 100 is given based on the Lucas-Washburn equation:

$${L}_{wd} = {Kt}^{0.5} \qquad ( 1 )$$

in which L_{wd} is the wicking distance, t is the elapsed time, and K is a constant that is dependent on the geometrical properties of the capillary tube (nano/microchannel) and the physical properties of the liquid. For purposes of this specific version, the constant K for high aspect ratio (width>>depth, as in the present case) is given by the following equation:

$$K = {( h γ cos θ / 3 μ )}^{0.5} \qquad ( 2 )$$

in which h is the height of the nano/microchannel, γ is the surface tension of the working fluid, θ is the advancing contact angle of the working fluid meniscus inside the nano/microchannels, and Ξ is the dynamic velocity of the working fluid. A linear variation of Equation 1 with t^{0.5} has been verified to hold valid for meniscus wicking inside the array of nano/microchannels. In the present example, the working fluid was filled in from only one of the two micro-reservoirs of the herein described exemplary nano/microchannel evaporator, keeping the remaining end reservoir initially empty. For purposes of this working example and experimental study, a high-speed camera captured a wicking video, which was later processed using a MATLAB script to obtain continuous wicking distance, per FIG. 3(a), confirming the linear relation between the wicking distance and the t^{0.5} proposed according to Equation 1. Furthermore, the liquid front velocity (V_{wf}) during the wicking process is shown in FIG. 3 (b) and was also obtained by image processing in which the liquid front velocity (V_{wf}) was measured by analyzing frames of the sliding drop; the frames were recorded using the high-speed camera. A custom written MATLAB algorithm was used to detect the wick front. After cropping out the desired area in the image, the image was converted into a binary (i.e., black & white) image. This conversion enabled easy tracking of the wick front as the black pixel on the wick front would always have value “0” and the vacant nanochannel ahead appearing as the white pixel would have value “1”.

The elapsed time elapsed (t) between frames was obtained from number of frames (nf) and captured frame rate (fps) of video. Velocity was obtained as,

$$Velocity = \frac{Δ L * fps}{p * nf} \qquad ( 3 )$$

in which ΔL is the difference in pixel distance of wick front from the end microreservoir of the evaporator in subsequent frames, and p is a calibrated pixel length (i.e., how many pixels would be in 1 mm).

The flow of liquid through the nanochannels 104 of the herein described evaporator 100 leads to the occurrence of disjoining pressure and the development of ultra-thin stagnant layers on the solid surface. V_{wf} drastically diminishes within approximately 250 seconds of wicking (L_{wd} ˜19 mm) due to viscous resistance, and approaches approximately 15 microns/second towards the end.

After complete wicking, the evaporator was kept on a computer-connected weighing scale to record the weight loss due to the evaporation of the working fluid, as shown in FIG. 3(c). The tube reservoirs were arranged so that the long tube (inset, FIG. 3(c)) with scale marking containing working fluid was kept plugged (i.e., closed) to prevent surface evaporation, while the remaining tube reservoir was left open to the atmosphere. The recorded weight loss (FIG. 3(c)) over a period of 2 hours was then calibrated against the drop in the level of working fluid in the right reservoir. The weight loss obtained from the weighing scale according to this specific study/example was 113.9 mg over 2 hours, as compared in working fluid level of 0.07 mL (or 117.6 gm) of working fluid. This equates to a difference of only about 3.2 percent between them. In accordance with this working example, the calibration of working fluid (FC72) weight loss was performed in two (2) stages. In a first stage, the leakage of working fluid through the plugged tube reservoirs was investigated. After complete wicking of the working fluid in the evaporator, both tube reservoirs were closed using rubber plugs. Subsequently, the whole system was kept on the weighing scale for an additional 2 hours. A negligible change in the weighing scale reading was observed, confirming the good sealing of the rubber plugs. In the second stage and to verify that the drop in volume of working fluid in the tube reservoir agrees with the weight loss recorded by the weighing scale, the micro/nanochannel evaporator was again kept on the weighing scale for 2 hours, but with one side of the tube reservoir open. The tube that was opened to atmophere resulted in a drop in volume of working fluid by 0.07±0.01 ml. The change is weight recorded by the weighing scale was: 113.9±0.1 mg. Given the density of this specific working fluid (FC72) as 1.68 g ml⁻¹, the resulting drop in volume in tube reservoir correlates well with the weighing scale readings.

This weight change-based approach of finding evaporative mass flux and subsequent evaporative heat flux is rather unconventional and independent of contact angle-based methodology that are extensively used in literature. Deviating from macroscale to nanoscale, meniscus shape, and hence contact angle accuracy, depends on numerous factors that include the resolution of the image, the refractive index of glass used, molecular interactions between fluid-solid surfaces, and contamination in confined spaces. Certainly, edge detection of the microscopic image of the liquid-vapor interface may not be an accurate technique for finding the contact angle. Studies show that there are inherent issues in confinement, such as significant variation between the actual and apparent contact angle and potential deformation of microstructure at the three-phase contact line under negative pressure. Although the current weight loss approach does not capture details of the interfacial phenomena, it does account for the macroscopic performance of the nanochannels of the evaporator made in accordance with this working example.

Evaporative mass flux (\ddot{m}ₑᵥ) in the absence of active heat flux was approximately 12.8 kn m⁻²s⁻¹, as obtained from the following equation:

$${\ddot{m}}_{ev} = \frac{Δ m}{{t}_{ev} * {A}_{nc}} \qquad ( 4 )$$

in which Δ m is the mass change of working fluid in the tube reservoir (kg), tₑᵥ is the total evaporation time (seconds), and A_{nc} is the total cross-sectional area of the nanochannels (m²). A_{nc} for purposes of this specific example, did not include nonfunctional/blocked nanochannels that were found to be 84 (out of 1100 total nanochannels according to this specific evaporator). Prior to evaluating the performance of the nanochannel evaporator, emissivity (ϵ) calibration of the evaporator top surface was performed as shown in FIG. 3(d). The temperature recorded by the IR camera and thermocouple matches well as ϵ=0.92, and this value of emissivity has been used herein.

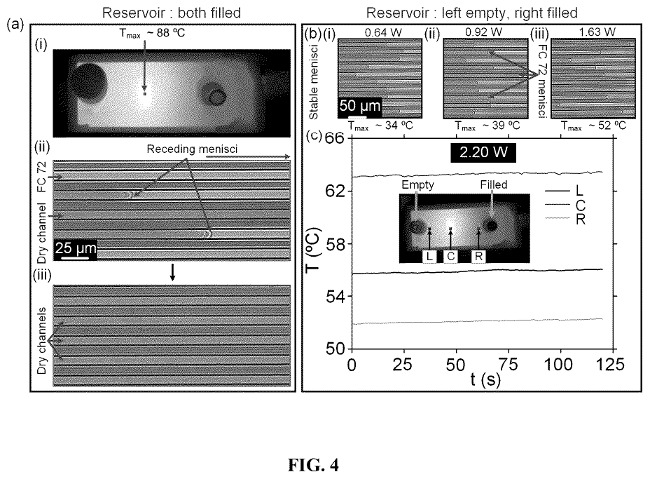

Initially, both end reservoirs of the evaporator 100 were filled with working fluid and allowed sufficient time to completely wick into the nanochannels 104 (like that shown in FIG. 2(d)), with sufficient additional working channel percent in the end reservoirs 108. Subsequently, the sample was then heated beyond its normal boiling point (˜56° C.) by supplying 5.53 W (11.8 W cm⁻²) while continuously monitoring the nanochannels 104 under the microscope. Interestingly, despite the surface of the evaporator 100 being at about 88° C. (FIG. 4(a)), no nucleation was observed. On the contrary, vigorous boiling was seen at the opening of micro-reservoirs 108. Nucleation did not occur in the nanochannel(s) 104 primarily due to the combination of disjoining pressure and the associated increase in energy required to increase pressure and displace liquid. Instead, heat from the heater was conducted laterally along the silicon wafer, causing the surface temperature at the micro-reservoirs 108 to rise above the boiling point of the working fluid. Following the dry out at the micro-reservoirs 108, the menisci receded rapidly (FIG. 4(a)) from the micro-reservoir at one end to the remaining end of the nanochannel evaporator 100.

To obtain stable menisci under heated conditions, the working fluid (e.g., FC72) was filled in only one of the end reservoirs 108 of the evaporator 100.

For purposes of this discussion, stable menisci refer to very little change ˜ + or −0.64 micrometers/second (maximum observed) in meniscus position after 20 minutes of steady power supply. Depending upon the supplied power, stable menisci were achieved (per FIG. 4(b)) regulated by working fluid evaporation rate and subsequent momentum transport governing the working fluid flow to the liquid-vapor interface. Four (4) levels of power input at the heater: 0.64, 0.92, 1.63 and 2.20 W (corresponding heat flux: 1.36, 1.96, 3.48, and 4.69 W/cm²) were utilized in the analysis of this specific nano/microchannel evaporator design. The distance at which the menisci attain a steady state is referred to as the wicking distance (L_{wd}), which is measured after confirming the meniscus stability as observed under the microscope. The temperature record by the IR camera for Q +or −2.2 W near the left end reservoir (L), right end reservoir (R), and above the heater (C) is shown in FIG. 4(c). The temperature near the right end reservoir was initially lower than that of the left counterpart reservoir due to the presence of the working fluid in the right end reservoir.

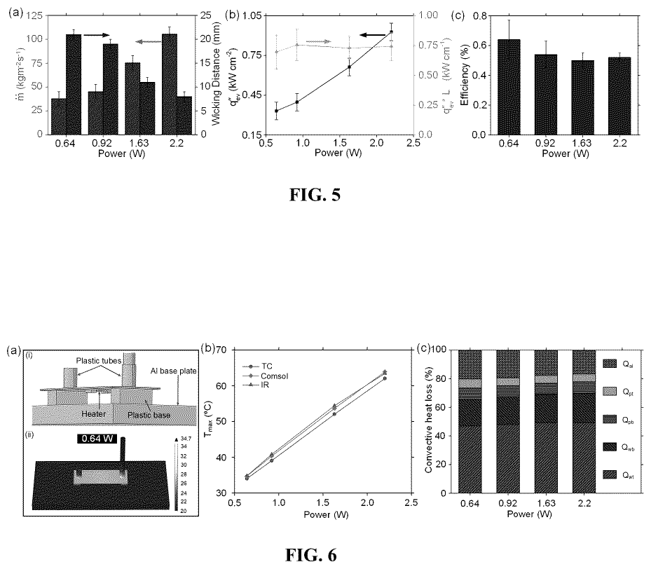

\ddot{m}ₑᵥ and L_{wd} for all four (4) supplied power levels are shown in FIG. 5(a). At 2.2 W, extremely high m ˜105.4 Kg m⁻¹ s was recorded. Increased power supply to 2.20 W caused a reduction in L_{wd} from 21 mm (at 0.64 W), however, the evaporator 100 maintained L_{wd}˜8 mm (at 2.20 W) at temperature ˜52° C. (measured near meniscus) and close to the boiling point of the working fluid (i.e., FC72). At steady state, the contribution of interfacial evaporation in cooling (Qₑᵥ) is given by the following relation:

$${Q}_{ev} = \frac{{ρ}_{1} Δ {Vh}_{fg}}{{t}_{ss}} \qquad ( 5 )$$

in which ρ is the density of the working fluid (FC72)=1.68 g cm⁻¹, ΔV is the change in working fluid (FC72) in the tube reservoir (mL), h_{fg} is the latent heat of vaporization of the working fluid FC72 (88 j g⁻¹) and tₛₛ is the duration of this working example after steady state has been achieved. ΔV is acquired over tₛₛ=30 minutes.

Steady state interfacial evaporative heat flux (q″ₑᵥ) for each supplied heat power is written as:

$${q}_{ev}^{″} = \frac{{Q}_{ev}}{{A}_{nc}} \qquad ( 6 )$$

in which A_{nc}=1.24×10⁻⁰⁵ cm² is the total cross-sectional area of the channels of the evaporator. Uncertainities associated with the weighing scale is about 0.1 mg. For the tube reservoir, the least count in scale marking is 0.01 ml. Based on these parameters, uncertainity in mass flux (Δ\ddot{m}ₑᵥ) is given as:

$$Δ {\ddot{m}}_{ev} = {\ddot{m}}_{ev} \sqrt{{( \frac{Δ ( Δ m )}{Δ m} )}^{2} + {( \frac{Δ {t}_{ev}}{{t}_{ev}} )}^{2} + {( \frac{Δ {A}_{nc}}{{A}_{nc}} )}^{2}} \qquad ( 7 )$$

where, Δm is mass change of the working fluid (FC72) in the tube reservoir during evaporation (kg), tₑᵥ is the total evaporation time(s), and A_{nc} is the total cross-sectional area of channels (m²) excluding blocked channels. Uncertainties in area calculation is given as:

$$\frac{Δ {A}_{nc}}{{A}_{nc}} = \sqrt{{( \frac{Δ h}{h} )}^{2} + {( \frac{Δ w}{w} )}^{2}} \qquad ( 8 )$$

where, Δh=1.5 nm, and Δw=0.263 μm are the error in channel height (h) and width (w), respectively. These are obtained by calculating standard deviation from the AFM height profile at extreme points of the channel.

Uncertainities in interfacial evaporation in cooling (Qₑᵥ, W) is written as:

$$Δ {Q}_{ev} = {Q}_{ev} \sqrt{{( \frac{Δ ( Δ V )}{Δ V} )}^{2} + {( \frac{Δ {t}_{ss}}{{t}_{ss}} )}^{2}} \qquad ( 9 )$$

where, Δtₛₛ is 1 s, Δ(ΔV)=0.01 ml.

Uncertainities in steady state interfacial evaporative heat flux (Δq″ₑᵥ) is given as:

$$Δ {q}_{ev}^{″} = {q}_{ev}^{″} \sqrt{{( \frac{Δ ( Δ V )}{Δ V} )}^{2} + {( \frac{Δ {t}_{ev}}{{t}_{ev}} )}^{2} + {( \frac{Δ {A}_{nc}}{{A}_{nc}} )}^{2}} \qquad ( 10 )$$

Uncertainities in product of steady state interfacial evaporative heat flux and wicking distance is given as:

$$Δ ( {q}_{ev}^{″} {L}_{wd} ) = ( {q}_{ev}^{″} {L}_{wd} ) {( \frac{Δ {q}_{ev}}{{q}_{ev}} )}^{2} + {( \frac{Δ {L}_{wd}}{{L}_{wd}} )}^{2} \qquad ( 11 )$$

where, ΔL_{wd} is the uncertainty in wicking distance measurement (1 mm), and q″ₑᵥ is steady state interfacial evaporative heat flux.

Uncertainities in nc-HP efficiency calculation is given as:

$$Δ {η}_{ev} = {η}_{ev} \sqrt{{( \frac{Δ {Q}_{ev}}{{Q}_{ev}} )}^{2} + {( \frac{Δ Q}{Q} )}^{2}} \qquad ( 12 )$$

Since, error in supplied power to the evaporator (ΔQ) is negligible as compared to error asociated with Qₑᵥ, the second term in Equation 11 can be omitted. Reference is further made to the following Table I for each of the foregoing at the various heat flux inputs:

TABLE I
Errors and uncertainties related to various parameters.

| | | |
|---|---|---|
| | Mean | Standard Deviation/ |
| Parameter (unit) | Value | Uncertainty |

0.64 W

| | | |
|---|---|---|
| \ddot{m}ₑᵥ (kgm⁻²s⁻¹) | 37.6 | 7.5 |
| Qₑᵥ (mW) | 4.11 | 0.82 |
| q″ₑᵥ (kWcm⁻²) | 0.33 | 0.06 |
| q″ₑᵥL_{wd} (kWcm⁻¹) | 0.70 | 0.14 |
| ηₑᵥ (%) | 0.64 | 0.13 |

0.64 W

| | | |
|---|---|---|
| \ddot{m}ₑᵥ (kgm⁻²s⁻¹) | 45.2 | 7.5 |
| Qₑᵥ (mW) | 4.93 | 0.82 |
| q″ₑᵥ (kWcm⁻²) | 0.39 | 0.06 |
| q″ₑᵥL_{wd} (kWcm⁻¹) | 0.76 | 0.13 |
| ηₑᵥ (%) | 0.54 | 0.09 |
| | 1.63 W | |
| \ddot{m}ₑᵥ (kgm⁻²s⁻¹) | 75.3 | 7.5 |
| Qₑᵥ (mW) | 8.21 | 0.82 |
| q″ₑᵥ (kWcm⁻²) | 0.66 | 0.06 |
| q″ₑᵥL_{wd} (kWcm⁻¹) | 0.73 | 0.09 |
| ηₑᵥ (%) | 0.50 | 0.05 |
| | 2.20 W | |
| \ddot{m}ₑᵥ (kgm⁻²s⁻¹) | 105.4 | 7.5 |
| Qₑᵥ (mW) | 1.15 | 0.82 |
| q″ₑᵥ (kWcm⁻²) | 0.93 | 0.06 |
| q″ₑᵥL_{wd} (kWcm⁻¹) | 0.74 | 0.12 |
| ηₑᵥ (%) | 0.52 | 0.04 |

For a moving meniscus, q″ₑᵥ is also given by the following relationship:

$${q}_{ev}^{″} = {ρ}_{1} {h}_{fg} {v}_{f} \qquad ( 13 )$$

in which v_{f} is the liquid front velocity and for a flow through rectangular channel, this can be approximated as:

$${v}_{f} ∝ \frac{{h}^{2} Δ P}{μ {L}_{wd}} \qquad ( 14 )$$

where h is the height of the channel, ΔP is the capillary driving pressure over the wicking distance L_{wd}, and μ is the dynamic viscosity of the liquid. The inverse relationship between v_{f} and L_{wd} can be observed in FIGS. 3(a) and 3(b). From Equations (13) and (14), the following observations can be made:

$${q}_{ev}^{″} {L}_{wd} ∝ \frac{{ρ}_{1} {h}_{fg} {h}^{2} Δ P}{μ} \qquad ( 15 )$$

Equation (15) implies that even though q″ₑᵥ increases with supplied heat input (FIG. 5(b)), the product of interfacial evaporative heat flux and wicking distance remains uniform as verified with experimental results shown in FIG. 5(b). In the current study, the maximum q″ₑᵥ obtained was ˜0.93 kW cm⁻² and the average q″ₑᵥ L_{wd} was ˜0.73±0.02 kW cm⁻¹. Accordingly, a similar evaporator designed to maintain a shorter wicking distance L_{wd}˜100 μm can theoretically achieve q″ₑᵥ˜73 kW cm⁻², which is within the kinetic theory predictions of maximum q″ₑᵥ˜110 kW cm⁻². The efficiency of the evaporator (FIG. 5(c)) is written as:

$${η}_{ev} = \frac{{Q}_{ev}}{Q} \qquad ( 16 )$$

in which Q is supplied power to the evaporator. While local interfacial evaporative heat flux q″ₑᵥ) can attain ˜1 kW cm⁻² or higher as reported in various studies, its efficiency in actual device cooling is typically restricted or not reported. In this current study, ηₑᵥ for all four levels of supplied power was <1% due to the high q″ₑᵥ restricted only to a minuscule interfacial area inside the nanochannels. This aspect of nano/microstructured—based evaporators could be further investigated to enhance ηₑᵥ apart from the primary focus of achieving higher q″ₑᵥ.

While evaporative heat flux contributed <1% to the thermal management, other factors such as conduction through silicon and subsequent heat loss via natural convection reduced hotspot temperature. COMSOL simulations were performed for examining the hot spot temperature and associated convection heat losses in the presence of the herein described evaporator by comparison of experimental and simulation temperature values.

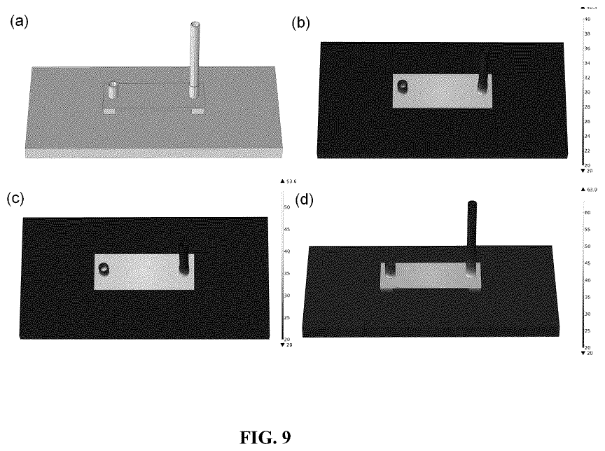

3D model and temperature distribution (for Qiₙ=0.64 W) on the working example that is herein described and obtained using a COMSOL simulation are shown in FIG. 6(a). All COMSOL simulations conducted were steady state study. Boundary conditions in the simulations were as follows: ambient temperature=20° C., ambient pressure=1 atm. To determine natural convection heat loss from different surfaces, the inbuilt surface integral function for heat flux was used. This method enabled individual heat loss from different components of the experimental setup to be determined. Dimensions of the specific components according to this working example and experimental study were as following:
Silicon and glass wafer: 80 mm by 30 mm by 500 μm
Heater: 7.1 mm by 6.6 mm by 500 μm
Electrodes: 6.6 mm by 3 mm by 1.5 mm
Plastic support base at both end of the evaporator: 20 mm by 10 mm by 10 mm
Aluminum base plate: 200 mm by 100 mm by 100 mm
Small hollow tube reservoir: outer radius 4 mm, 1 mm thick and 12 mm high cylinder over microreservoir
Long hollow tube reservoir: outer radius 3.5 mm 0.5 mm thick and 60 mm high cylinder over the microreservoir. Further reference is herein made to FIGS. 9(a)-(d).

It will be understood that the foregoing dimensions are specific to this experimental study and therefore any or all of these parameters can be suitably adjusted. A comparison of the maximum surface temperature obtained from simulation results and experiments (both by IR and thermocouple) for each of the supplied power is shown in FIG. 6(b). As presented, there is an excellent agreement between the IR measurements and the COMSOL simulation results, and the corresponding percentage of the natural convection heat loss from various sources is shown in FIG. 6(c). The convection losses were from the aluminum base plate (Qₐₗ), the tube reservoirs (Qₚₜ), the plastic base beneath the evaporator (Q_{pb}), the bottom silicon surface of the evaporator (Q_{wb}), and the top glass surface of the evaporator (Q_{wt}), each of which were estimated by performing COMSOL simulations. As expected, the heat loss from the top surface of the herein described evaporator (Q_{wt}) contributes the greatest amount of heat loss in each case. Even though the maximum qₑᵥ was ˜0.93 kWcm⁻² for Qᵢₙ=2.2 W, net cooling provided only by evaporation was ˜11.5 mW and cooling was predominantly accomplished by heat losses via natural convection on this experimental setup. Similarly, previous studies that demonstrate very high qₑᵥ utilizing various types of porous structures, nano porous membranes, porous wicks among others, to enhance evaporative heat flux require a new perspective to assess the net effect of such qₑᵥ improvements on device cooling and associated heat losses through other components.

Conclusively, this systemic approach of fabricating a practical nano/microchannel-based evaporator and its performance was successfully conducted and evaluated, using dielectric FC72 as the working fluid. As previously noted, the herein described evaporator according to this embodiment included 1100 nanochannels of cross-sectional area 122 nm×10 microns running across a length of approximately 48 mm between a pair of end micro-reservoirs 108. This specific evaporator 100 was designed to facilitate the direct measurement of the change in mass during evaporation of the working fluid FC72, and thus the interfacial evaporative heat flux (qev) was estimated without contact angle measurement of the meniscus in the various nanochannels and the associated uncertainties that accompnay such an approach. When the channels and both end reservoirs were filled with the working fluid, nucleation was not observed even at temperatures of ˜88° C., which are well beyond the boiling point of the working fluid (FC72).

When the nanochannels were filled with FC72 using only a single micro-reservoir while the remaining reservoir was open to the atmosphere, stable evaporating menisci were obtained at different power inputs. At lower heat flux, a maximum steady state qₑᵥ˜0.93 kW cm⁻² was achieved at a maximum surface temperature of ˜63° C. The maximum variation of temperature in the evaporator was ˜11° C. from the central hot spot to the end reservoir at a power input of 2.20 W. Depending on the given heat flux, the wicking distance ranged from 21 to 8 mm. The product of steady qₑᵥ and the wicking distance was found to be nearly constant for all four (4) applied power inputs. The foregoing suggests the possibility of achieving a high qev by tailoring the wicking distance, even under steady state, as compared to superior heat transfer performance during transient meniscus variation as traditionally reported in literature.

Another aspect of the herein described evaporator design is the evaporative efficiciency, i.e., the absolute contribution of the thermal management solution to the cooling of the hot spot, which is found to be restricted to <1% due to the limited meniscus area in the nanochannels 104. Numerical simulations were performed to calculate the contribution of different components of heat losses in the herein described evaporator system. As a result, appropriate modifications in nanochannel design, such as incorporating nanostructures, were required to improve the interfacial area. The cross-section of the formed channels can vary depending on the thermal load, since the thermal load governs the transport of the working fluid from the micro-reservoir to the hot spot. Furthermore, the channels can be designed with a reduced length (˜2 cm) that corresponds to the maximum stable wicking distance at the desired working power, which would not only minimize the convection heat losses from the surface, but also provide the additional benefits of compact size and being lightweight. These suggested modifications could have a significant impact on the thermal management in different electronic systems.

In terms of operation, the working liquid will be loaded from one of the reservoirs (108 in FIG. 1a) as it is a symmetric design. The working liquid will wick through the channels 104 due to surface tension of the fluid and to a limited extent due to temperature until the working liquid fills the channels 104. Please note that due to the strong capillarily in the channels 104, the liquid remains in each channel 104 forming a meniscus at its end, and liquid does not fill the other reservoir 108, keeping the remaining reservoir 108 dry. When heat is applied, the working liquid starts to evaporate at all menisci in all channels 104, thus dissipating the applied heat. Vapor generated in the channels 104 exits from the other non-filled (dry) reservoir 108. This generated vapor will be condensed, and in its liquid form, will be sent back to the liquid filled reservoir 108. At a higher heat load, the menisci reposition themselves closer to the liquid filled reservoir 108. At a very high heat load, the menisci will reach the liquid filled reservoir 108, thus completely drying out the channels 104 and the evaporator 100 will cease to function. However, the evaporator, including the array of channels 104 and reservoirs 108, can be scaled and suitably designed to meet the heat load requirements for any specific application. This scaling can be performed using Equation 15, in order to determine suitable lengths, cross section areas, and material of the nanochannels, as well as a choice of a suitable working fluid.

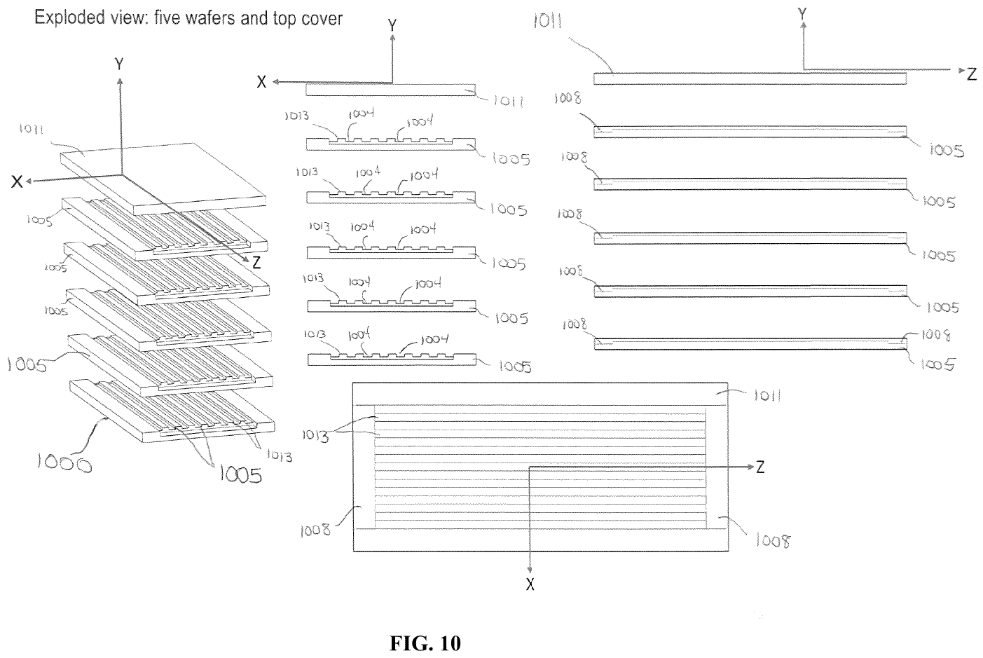

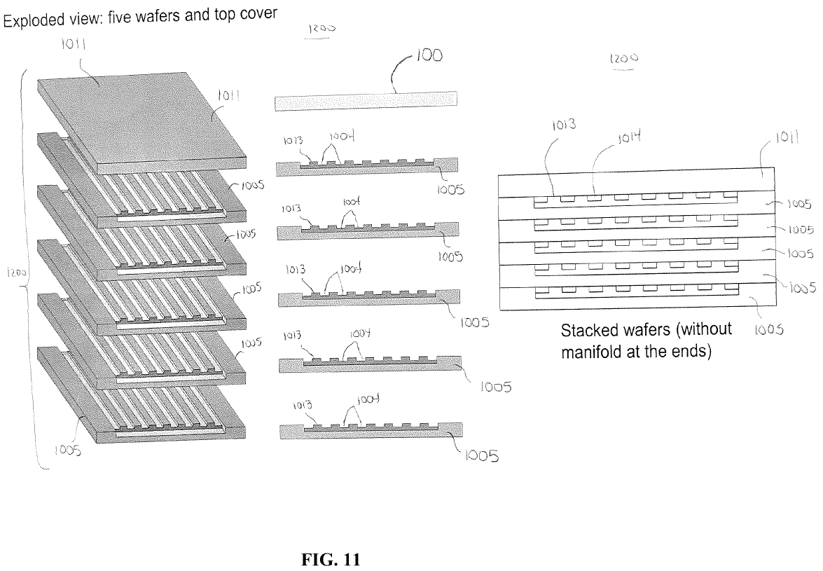

The use of a single planar nano/microchannel evaporator, as previously described, can be further expanded to provide enhanced thermal management, for example, in enabling high heat flux dissipation in various electronic devices and applications. Therefore and according to another exemplary embodiment, a plurality of nano/micro-channel evaporators, for example those previously described and shown in FIG. 1 or structural variants thereof, can be arranged in a vertically stacked configuration, as shown in FIGS. 10 and 11. For purposes of this specific example, an evaporator 1200 is made up of five (5) supporting planar substrates 1005 (also referred to here as evaporators 1000), each having an array of nano/microchannels 1004 and end reservoirs 1008 formed in an upper surface, are disposed in a parallel and vertically stacked manner relative to one another. It will be readily apparent, however, that the overall number of single planar evaporators for stacking can be suitably varied, depending on any intended application and use/device.

In this example, fabrication is performed similarly upon the individual supporting planar structures 1005, each including an array of parallel nano/micro-channels 1004 being formed in a silicon wafer or similar supporting planar structure 1005, including a set of ridges 1013 formed between each of the formed channels 1004, as previously discussed. In addition, each of the supporting planar structures 1005 include formed end reservoirs 1008 in fluid communication at respective ends of the array of nano/microchannels 1004. As shown in FIG. 11, a cover/substrate 1009 is disposed only over the uppermost stacked evaporator 1000, wherein the cover/substrate can be glass or other suitable material.

The plurality of supporting planar structures 1005 are vertically stacked one above the other and in intimate contact with one another, as shown in FIGS. 10 and 11. It should further be noted that each supporting planar structure 1005 can have an overall length varying from few nanometers to several centimeters, a width dimension varying from few nanometers to several centimeters, and a thickness varying from few nanometers to several centimeters. It should further be noted that each channel in each formed array of channels 1004 can be defined by a depth varying from few nanometers to several millimeters, a width dimension varying from few nanometers to several millimeters and a length dimension varying from few nanometers to several centimeters, in which the length of the formed channels 1004 axially or linearly extend into the end reservoirs 1008, whose dimensions can also be suitably varied.

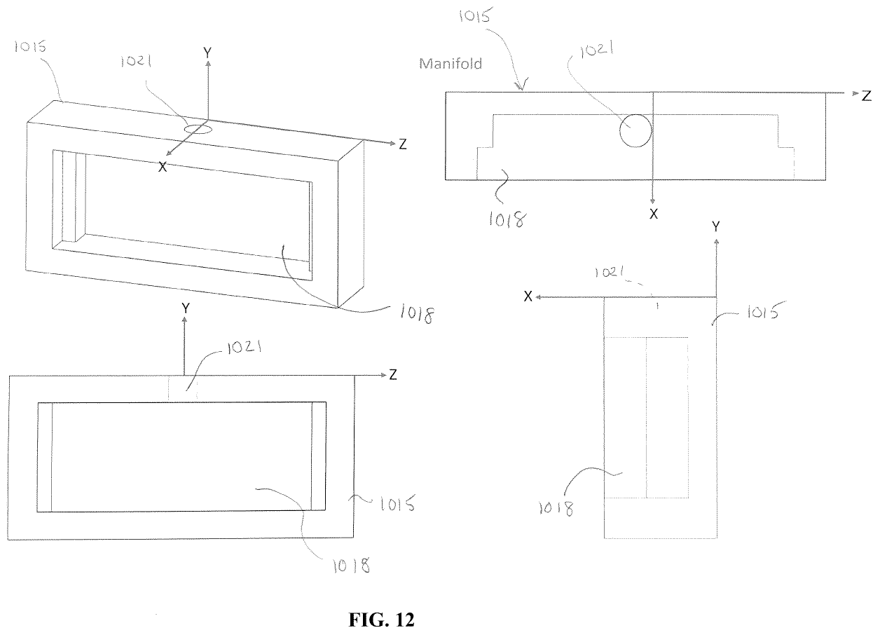

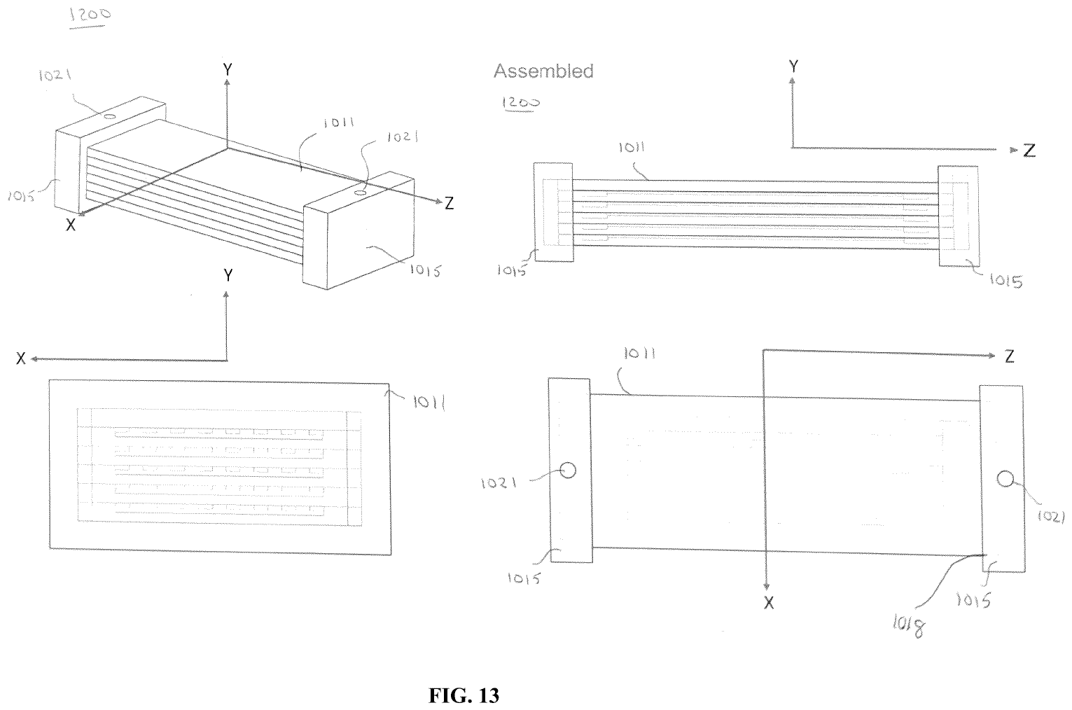

As shown in FIGS. 12 and 13, each of the ends of the supporting planar structures 1005 according to this exemplary embodiment are coupled to a manifold 1015, the purpose of which is to provide leak-free fluid supply to the individual supporting planar structures 1005, to remove fluid from the evaporator 1000, and also serve the purpose of reservoirs for any or all of the supporting planar structures 1005, if needed. The design, geometry, dimensions and material of the manifold 1015 can be varied as desired by the evaporation dimension, the heat dissipation fluid that is used, as well as other constraints put forth by the specific application. An exemplary version, as most clearly shown in FIG. 12, shows a solitary member 1015 having a stepped side cavity 1018 that is appropriately sized to receive one end of the stacked evaporators 1000. The use of a side cavity is optional and therefore is not necessarily required. For example, the manifold could alternatively be fabricated integrally with the planar supporting structures 1005. An opening 1021 is formed within a top or uppermost surface of the manifold 1015 according to this specific embodiment for permitting the ingress and egress of a suitable heat dissipative fluid, such as FC72. Accordingly, there is no requirement for the cover/substrate 1009 to include an opening in relation to the end reservoir(s) 1008, although openings could be provided for at least the uppermost end reservoirs 1008. It will also be understood that other suitable configurations can be realized.

An exemplary version of the assembled evaporator assembly 1200 is shown in FIG. 13 that includes the individually stacked supporting planar structures 1005 as retained by a pair of manifolds 1015 at respective ends, the manifolds 1015 each including the stepped side cavity 1018 for retaining the supporting planar structures 1005. The operation of the evaporator 1200 for each of the individual planar supporting structures 1005 is similar to that previously described. That is, working liquid will be loaded at only one of the manifold openings 1021 (the choice of opening 1021 used for fill does not matter as the evaporator 1200 is a symmetric design). The working liquid will wick through that manifold 1015 and reservoirs 1008 at that end, until the working liquid completely fills all the channels 1004 in all the stacked supporting planar structures 1005. Please note that due to the strong capillarily in the channels 1004, the liquid remains in each channel 1004 forming a meniscus at its end, and liquid does not fill the other reservoirs 1008 or the remaining manifold 1015, thus keeping them dry. When heat is applied, the working liquid starts to evaporate at the menisci in all the channels 1004 in each stack, thus dissipating the applied heat. Vapor generated in all the channels 1004 leaves from the other non-filled (dry) reservoir 1008 to its corresponding manifold 1015 and out of the manifold opening. This generated vapor will be condensed, and in its liquid form, will be sent back to the liquid filled manifold 1015.

More specifically, heat can flow from an electronic device in use (not shown), which can be present beneath the evaporator stack, and more specifically to the supporting planar structure 1005 closest to the electronic device. The heat developed by the electronic device can then transfer from one evaporator 1000, which is attached to the hot spot to the next vertically stacked evaporator 1000 through the substrate 1005 that join adjacent evaporators 1000, as well as the ridges 1013 present between the array of formed channels 1004.

The connection between the stacked evaporators 1000 provides a pathway for conduction heat transfer through the stacked evaporator 1200, meaning heat is being distributed among all the evaporators 1000. Subsequently, in each of the vertically stacked evaporators 1000, the heat is transferred to the working liquid, which undergoes phase change into vapor form which then exits through the manifold 1015, thereby carrying the heat away from the electronic device. So, in order to effectively cool down the electronic device, the overall heat transfer mechanism in the stacked evaporator 1000 is dominated by the conduction in the solid to spread out the heat to each stack followed by evaporation of the working liquid from the meniscus in each channel 1004.

While the evaporator has been described in terms of particular variations and illustrative figures, those of ordinary skill in the art will recognize that the concepts described by this disclosure are not limited to the variations or figures described. For example, each of the evaporators that have been described herein are defined by a rectilinear configuration. It will be understood, however, that the evaporators can alternatively assume a circular or other suitable polygonal shape. Moreover, the nano/micro-channels in each evaporator or in the case of the stacked configuration, in each evaporator level, can be varied relative to other arrays of channels.

In addition, where methods and steps described above indicate certain events occurring in certain order, those of ordinary skill in the art will recognize that the ordering of certain steps may be modified and that such modifications are in accordance with the variations of the invention. Additionally, certain of the steps may be performed concurrently in a parallel process when possible, as well as performed sequentially as described above. Further, the material of which each evaporator is made can be varied extensively if such materials and evaporators can be attached to one another; examples of such materials include silicon, copper, aluminum, etc. Coatings of various materials can also be present partially or fully on each surface of the evaporators. The fluid which flows through the evaporator can also be varied extensively to satisfy the heat dissipation requirements; examples of such fluids include FC72, water, and ethylene glycol, among others. Therefore, to the extent there are variations, which are within the spirit of the disclosure or equivalent to the inventive concepts found in the appended claims, it is the intent that this patent will cover those variations as well.

To the extent that the claims recite the phrase “at least one of” in reference to a plurality of elements, this is intended to mean at least one or more of the listed elements, and is not limited to at least one of each element. For example, “at least one of an element A, element B, and element C,” is intended to indicate element A alone, or element B alone, or element C alone, or any combination thereof. “At least one of element A, element B, and element C” is not intended to be limited to at least one of an element A, at least one of an element B, and at least one of an element C.

This Detailed Description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes,” or “contains” one or more steps or elements possesses those one or more steps or elements, but is not limited to possessing only those one or more steps or elements. Likewise, a step of a method or an element of a device that “comprises,” “has,” “includes,” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description set forth herein has been presented for purposes of illustration and description, but is not intended to be exhaustive or limited to the form disclosed. Many modifications and variations will be apparent to those of ordinary skill in the art without departing from the scope and spirit of the disclosure. The embodiment was chosen and described in order to best explain the principles of one or more aspects set forth herein and the practical application, and to enable others of ordinary skill in the art to understand one or more aspects as described herein for various embodiments with various modifications as are suited to the particular use contemplated and in accordance with the following appended claims. Additional embodiments include any one of the embodiments described above and described in any and all exhibits and other materials submitted herewith, where one or more of its components, functionalities or structures is interchanged with, replaced by or augmented by one or more of the components, functionalities or structures of a different embodiment described above and as set forth in the following appended claims.

### PARTS LIST FOR FIGS. 1(a)-13

100 nano/microchannel evaporator
104 array of nano/microchannels
105 supporting structure
108 reservoirs, end
109 opening(s)
111 cover or covering structure
113 ridges
1000 evaporators
1004 array of channels
1005 supporting planar structure
1008 end reservoir(s)
1009 openings
1011 cover/covering structure
1013 ridges
1015 manifold
1018 side cavity, manifold
1021 opening, top, manifold
1200 evaporator

1. An evaporator configured for thermal management of one or more electronic devices, the evaporator comprising
one or more supporting planar structures;
an array of channels formed in a surface of each of the one or more supporting planar structures, each of the channels of the array being in parallel relation to one another; and
a pair of reservoirs in fluidic communication with the array of channels, each reservoir being disposed at an opposing end of the evaporator in which at least one of the reservoirs contains a quantity of a heat-dissipating fluid.

2. The evaporator according to claim 1, further comprising a plurality of the supporting planar structures disposed in a vertically stacked arrangement.

3. The evaporator according to claim 1, wherein the heat dissipating fluid is FC72.

4. The evaporator according to claim 1, further comprising a cover/substrate disposed over the one or more supporting planar structures.

5. The evaporator according to claim 4, wherein the cover/substrate comprises at least one opening aligned with one of the reservoirs to permit ingress of the heat dissipating fluid into the evaporator.

6. The evaporator according to claim 5, wherein the cover/substrate is made from a transparent material.

7. The evaporator according to claim 2, further comprising at least one manifold configured to retain the stacked configuration of supporting planar structures at opposing ends thereof.

8. The evaporator according to claim 7, wherein the at least one manifold is defined by a cavity that is shaped and sized to fit the respective ends of the stacked arrangement of supporting planar structures.

9. The evaporator according to claim 8, wherein the at least one manifold includes an opening to allow for the heat dissipative fluid to ingress the evaporator.

10. The evaporator according to claim 1, wherein the array of channels are nanochannels.

11. The evaporator according to claim 1, wherein the end reservoirs are microreservoirs.

12. A method for enabling thermal management of electronic devices, the method comprising:
providing an evaporator sized and configured for placement in relation to an electronic device; and
forming the evaporator from one or more supporting structures, each of the supporting structures including an array of channels formed on a surface of the supporting substrate, and through which a quantity of heat dissipating fluid is configured to flow relative to an end reservoir also formed in the supporting structure and fluidly connected to the array of nano/microchannels in which a cover is provided onto the one or more supporting structures;
and
providing a heat dissipating fluid within at least one of the reservoirs, the heat dissipating fluid being configured to produce heat transfer via evaporation relative to the electronic device as the heat-dissipative fluid is caused to wick along the array of nano/microchannels.

13. The method according to claim 12, including forming the evaporator by disposing a plurality of supporting planar structures in a vertically stacked arrangement, in which each of the supporting planar structures comprises a formed array of nano or micro sized channels.

14. The method according to claim 13, further comprising disposing at least one manifold in to respective ends of the vertically stacked arrangement of supporting structures.

15. The method according to claim 12, in which the heat dissipating fluid is FC72.

16. The method according to claim 14, wherein the at least one manifold is configured with at least one opening for the ingress and egress of heat dissipative fluid.

17. The method according to claim 14, wherein the at least one manifold includes a side opening shaped and configured for receiving an end of the vertically stacked arrangement of the supporting planar structures.
